(19) United States
(12) Patent Application Publication
(10) Pub. No.: US 2012/0264273 A1
(43) Pub. Date: Oct. 18, 2012

(54) SEMICONDUCTOR DEVICES AND METHODS OF FABRICATING THE SAME

(75) Inventors: YounSeon KANG, Yongin-si (KR); Youngkuk Kim, Seoul (KR); Kiseok Suh, Hwaseong-si (KR)

(73) Assignee: Samsung Electronics Co., Ltd., Suwon-si (KR)

(21) Appl. No.: 13/421,280

(22) Filed: Mar. 15, 2012

(30) Foreign Application Priority Data
Apr. 13, 2011 (KR) 10-2011-0034321

(51) Int. Cl. H01L 21/02

(52) U.S. Cl. 438/382; 257/E21.004

(57) ABSTRACT

Semiconductor devices and methods of fabricating a semiconductor device are provided. The method includes forming a conductive region in a substrate and forming a dielectric layer on the substrate including the conductive region. The dielectric layer has an opening that exposes the conductive region. A buffer semiconductor pattern having a single crystalline state is formed on the exposed conductive region. A filling semiconductor pattern is formed in the opening using an epitaxial process that employs the single crystalline buffer semiconductor pattern as a seed layer. Related devices are also provided.

### CROSS-REFERENCE TO RELATED APPLICATIONS

This U.S. non-provisional patent application claims priority under 35 U.S.C. §119 to Korean Patent Application No. 10-2011-0034321, filed on Apr. 13, 2011, the entirety of which is incorporated by reference herein.

### BACKGROUND OF THE INVENTION

1. Field of the Invention

The general inventive concept relates to semiconductor devices and methods of fabricating the same.

2. Description of the Related Art

As the electronic industry becomes more highly developed, integration density of semiconductor memory devices has been gradually increased. The integration density of the semiconductor memory devices may act as an important factor that influences costs of the semiconductor memory devices. That is, the higher the integration density of the semiconductor memory devices is, the lower the costs of the semiconductor memory devices are. Thus, the improvement of the integration density of the semiconductor memory devices has been increasingly demanded. In general, the integration density of the semiconductor memory devices may be determined by a planar area that a unit cell of the semiconductor memory devices occupies. As a result, the integration density of the semiconductor memory devices may be subject to process techniques for forming fine patterns. However, there may be some limitations in increasing the integration density of the semiconductor memory devices due to high costs of equipment used in fabrication of the semiconductor memory devices and/or difficulties of fabrication processes.

### SUMMARY OF THE INVENTION

Embodiments of the inventive concept are directed to methods of fabricating a semiconductor device and semiconductor devices fabricated thereby.

Additional features and utilities of the present general inventive concept will be set forth in part in the description which follows and, in part, will be obvious from the description, or may be learned by practice of the present general inventive concept.

Exemplary embodiments of the present general inventive concept provide a method of fabricating a semiconductor device, the method including: forming a conductive region in a substrate and forming a dielectric layer on the substrate including the conductive region. The dielectric layer has an opening that exposes the conductive region. A buffer semiconductor pattern having a single crystalline state is formed on the exposed conductive region. A filling semiconductor pattern is formed in the opening using an epitaxial process that employs the buffer semiconductor pattern as a seed layer.

In an embodiment of the present general inventive concept, forming the single crystalline buffer semiconductor pattern may comprise forming a preliminary semiconductor pattern having an amorphous state or a polycrystalline state in the opening and crystallizing the preliminary semiconductor pattern. Forming the preliminary semiconductor pattern may include performing an epitaxial process using the conductive region exposed by the opening as a seed layer. Forming the preliminary semiconductor pattern may include depositing a preliminary semiconductor layer to fill the opening and etching a portion of the preliminary semiconductor layer. A vertical thickness of the preliminary semiconductor pattern may increase as it becomes closer to a sidewall of the opening. Crystallizing the preliminary semiconductor pattern may include irradiating a laser onto the preliminary semiconductor pattern or heating the preliminary semiconductor pattern.

In an embodiment of the present general inventive concept, the conductive region may include a metal-semiconductor compound material. Forming the conductive region may include forming a metal layer on the substrate, applying a first annealing process to the substrate, removing the metal layer and applying a second annealing process to the substrate. The second annealing process may be performed at a higher temperature than the first annealing process.

In an embodiment of the present general inventive concept, the substrate may have a first conductivity type. Forming the conductive region may include injecting dopants of a second conductivity type into the substrate. Forming the single crystalline buffer semiconductor pattern may include crystallizing an upper portion of the conductive region exposed by the opening.

In an embodiment of the present general inventive concept, the conductive region may extend in a first direction, and the conductive region may have a polycrystalline state or an amorphous state.

In an embodiment of the present general inventive concept, forming the filling semiconductor pattern may include performing a planarization process using the dielectric layer as a planarization stop layer after the epitaxial process.

In an embodiment of the present general inventive concept, the method may further include forming a semiconductor pillar by respectively injecting first dopants and second dopants into a lower portion and an upper portion of the filling semiconductor pattern, and forming a variable resistive pattern on the semiconductor pillar.

In another embodiment of the present general inventive concept, the semiconductor device comprises a conductive region having an amorphous state or a polycrystalline state disposed in a substrate to extend in a first direction and a dielectric layer on the substrate. The dielectric layer has an opening that exposes the conductive region. A single crystalline semiconductor pillar is disposed in the opening to contact the conductive region. The single crystalline semiconductor pillar includes first and second doped portions which are sequentially stacked. The first and second doped portions are doped with conductivity type dopants which are different from each other. A variable resistive pattern is disposed on the semiconductor pillar.

In an embodiment of the present general inventive concept, a bottom surface of the single crystalline semiconductor pillar may be located at a lower level than a top surface of the conductive region. A portion of a sidewall of the single crystalline semiconductor pillar may be covered with the conductive region.

Exemplary embodiments of the present general inventive concept also provide a method of fabricating a highly integrated semiconductor device, the method including: forming a conductive region in a substrate; providing a dielectric layer on the substrate, the dielectric layer having at least one perforation, wherein the at least one perforation uncovers at least a portion of the conductive region; forming a single crystalline buffer semiconductor pattern on the uncovered conductive region; and using an epitaxial process to form a filling semiconductor pattern in the at least one perforation wherein the single crystalline buffer semiconductor pattern is a seed layer.

Exemplary embodiments of the present general inventive concept also provide a method of fabricating a highly integrated semiconductor device in a fabricated semiconductor device formed of a substrate having a conductive region thereon, the method including: forming a perforated dielectric layer on the conductive region to provide at least one opening having an uncovered conductive region; forming a single crystalline buffer semiconductor pattern on the at least one uncovered conductive region; and using an epitaxial process to form a filling semiconductor pattern in the at least one opening wherein the single crystalline buffer semiconductor pattern is a seed layer.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a circuit diagram illustrating a semiconductor device according to an embodiment of the present general inventive concept.

FIG. 2A is a plan view illustrating a semiconductor device according to an embodiment of the present general inventive concept.

FIG. 2B is a cross-sectional view taken along a line I-I′ of FIG. 2A to illustrate a semiconductor device according to the embodiment of FIG. 2A.

FIG. 2C is a cross-sectional view taken along a line II-II′ of FIG. 2A.

FIGS. 3A to 7A are plan views illustrating a method of fabricating a semiconductor device according to another embodiment of the inventive concept.

FIGS. 3B to 7B are cross-sectional views taken along a line I-I′ of FIGS. 3A to 7A respectively.

FIGS. 3C to 7C are cross-sectional views taken along a line II-II′ of FIGS. 3A to 7A, respectively, to illustrate a method of fabricating a semiconductor device according to a first embodiment of the inventive concept.

FIGS. 8 to 10 are cross-sectional views taken along a line I-I′ of FIG. 2A to illustrate a first modified embodiment of a method of fabricating a semiconductor device according to a first embodiment of the inventive concept.

FIG. 11 is a cross-sectional view taken along a line I-I′ of FIG. 2A to illustrate a second modified embodiment of a method of fabricating a semiconductor device according to a first embodiment of the inventive concept.

FIG. 12A is a plan view illustrating a semiconductor device according to a second embodiment of the inventive concept.

FIG. 12B is a cross-sectional view taken along a line I-I′ of FIG. 12A to illustrate a semiconductor device according to a second embodiment of the inventive concept.

FIG. 12C is a cross-sectional view taken along a line II-II′ of FIG. 12A to illustrate a semiconductor device according to a second embodiment of the inventive concept.

FIGS. 13A to 15A are plan views illustrating a method of fabricating a semiconductor device according to a second embodiment of the inventive concept.

FIGS. 13B to 15B are cross-sectional views taken along a line I-I′ of FIGS. 13A to 15A, respectively, to illustrate a method of fabricating a semiconductor device according to a second embodiment of the inventive concept.

FIGS. 13C to 15C are cross-sectional views taken along a line II-II′ of FIGS. 13A to 15A, respectively, to illustrate a method of fabricating a semiconductor device according to a second embodiment of the inventive concept.

FIG. 16 is a schematic block diagram illustrating an example of electronic systems including semiconductor devices according to embodiments of the inventive concept.

FIG. 17 is a schematic block diagram illustrating an example of memory cards including semiconductor devices according to embodiments of the inventive concept.

### DETAILED DESCRIPTION OF THE PREFERRED EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms.

Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limiting the scope of the inventive concept.

It will be also understood that although the terms first, second, third, etc. may be used herein to describe various elements, these elements should not be limited by these terms. These terms are only used to distinguish one element from another element. Thus, a first element in some embodiments could be termed a second element in other embodiments without departing from the teachings of the present invention general inventive concept. Exemplary embodiments of aspects of the present inventive concept explained and illustrated herein include their complementary counterparts. The same reference numerals or the same reference designators denote the same elements throughout the specification.

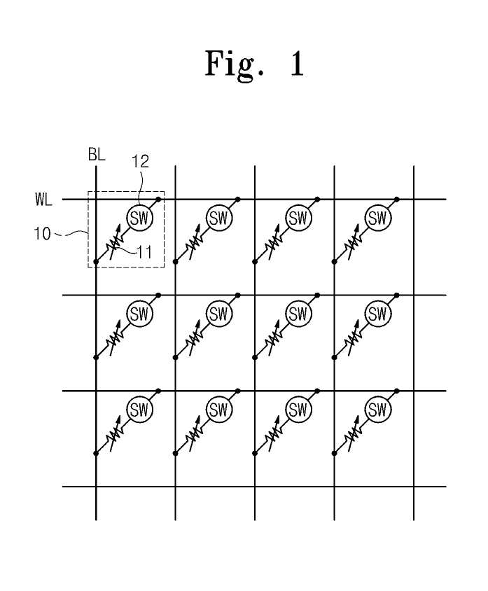

FIG. 1 is a circuit diagram illustrating a semiconductor device according to an embodiment of the present inventive concept.

Referring to FIG. 1, a plurality of memory cells 10 may be arrayed in a matrix form. Each of the memory cells 10 may include a variable resistive element 11 and a selection element 12 which are serially connected to each other. The variable resistive element 11 and the selection element 12 may be connected to one of a plurality of bit lines BL and one of a plurality of word lines WL, respectively.

A phase state of the variable resistive element 11 may be determined according to an amount of a current supplied through the bit line BL connected thereto. One terminal of the selection element 12 may be connected to the variable resistive element 11, and the other terminal of the selection element 12 may be connected to one of the word lines WL. The selection element 12 may control a current that flows through the variable resistive element 11 in response to a voltage applied to the word line WL connected to the selection element 12. The selection element 12 may include a diode.

Hereinafter, although the semiconductor devices according to embodiments of the present general inventive concept are described in conjunction with phase changeable random access memory (PRAM) devices employing phase changeable materials such as the variable resistive element 11, the inventive concept is not limited to the PRAM devices (which may be referred to as phase change memory devices). That is, the inventive concept may be equally applicable to memory devices employing other variable resistors, for example, resistive RAM (RRAM) devices, magnetic RAM (MRAM) devices, or ferroelectric RAM (FRAM) devices. The phase changeable material may be changed into an amorphous state having a relatively high resistance or a crystalline state having a relatively low resistance in accordance with a heating temperature and cooling (or quenching) time of the phase changeable material. When the memory cell 10 is referred to as being in a set state, the phase changeable material of the memory cell 10 may have an amorphous state. In contrast, when the memory cell 10 is referred to as being in a reset state, the phase changeable material of the memory cell 10 may have a crystalline state. In the phase change memory devices, when current flows through a lower electrode serially connected to the phase changeable material, heat energy (e.g., measured in joules) may be generated at an interface between the lower electrode and the phase changeable material to heat the phase changeable material. The heat energy (e.g., measured in joules) may be proportional to a resistivity of the phase changeable material and a supply time of the current flowing through the lower electrode.

In the event that the phase changeable material is heated to a temperature that is higher than the melting point thereof for a first duration and cooled down rapidly, the phase changeable material may be transformed into an amorphous state. On the contrary, when the phase changeable material is heated to a temperature within the range of a crystallization temperature thereof to the melting temperature for a second duration (longer than the first duration) and is cooled down, the phase changeable material may be transformed into a crystalline state. Thus, it is possible to discriminate whether the information stored in the memory cell 10 is a logic “1” or a logic “0” by detecting the current that flows through the phase changeable material in a read mode.

Now, a semiconductor device according to a first embodiment of the inventive concept will be described below.

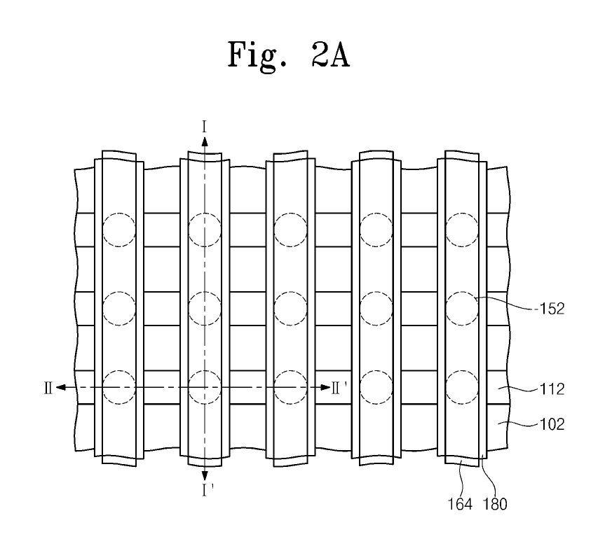

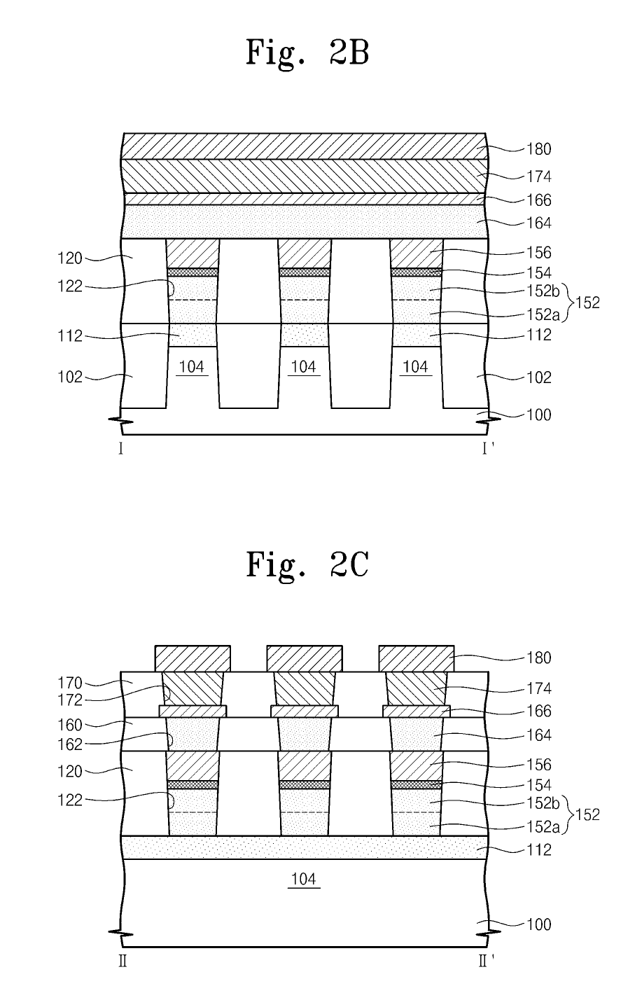

FIG. 2A is a plan view illustrating a semiconductor device according to a first embodiment of the inventive concept. FIG. 2B is a cross-sectional view taken along a line I-I′ of FIG. 2A to illustrate a semiconductor device according to a first embodiment of the inventive concept, and FIG. 2C is a cross-sectional view taken along a line II-II′ of FIG. 2A to illustrate a semiconductor device according to a first embodiment of the inventive concept.

Referring to FIGS. 2A, 2B and 2C, a substrate 100 doped with dopants of a first conductivity type may be provided. The substrate 100 may include a semiconductor material. For example, the substrate 100 may include a silicon substrate, a germanium substrate or a silicon-germanium substrate.

Isolation patterns 102 may be disposed in the substrate 100. The isolation patterns 102 may extend in a first direction to have a line shape. The isolation patterns 102 may define active portions 104. Each of the active portions 104 may correspond to a portion of the substrate 100 disposed between the adjacent isolation patterns 102. The active portions 104 may extend in the first direction to be parallel with each other. The active portions 104 may be doped with dopants of the first conductivity type.

Conductive regions 112 may be disposed in the active portions 104, respectively. The conductive regions 112 may include a metal-semiconductor compound material layer such as a metal silicide layer. Each of the conductive regions 112 may correspond to a metal silicide layer containing the same semiconductor element as the substrate 100. The conductive regions 112 may have a polycrystalline state or an amorphous state. The conductive regions 112 may extend in the first direction to have a line shape. The conductive regions 112 may correspond to the word lines WL as is illustrated illustrate in FIG. 1.

A dielectric layer 120 may be disposed on an entire top surface of the substrate having the conductive regions 112. The dielectric layer 120 may include an oxide layer, a nitride layer and/or an oxynitride layer.

A plurality of semiconductor pillars 152 may be disposed in first openings 122 penetrating the dielectric layer 120, respectively. Each of the semiconductor pillars 152 may be electrically connected to one of the conductive regions 112. The semiconductor pillars 152 may be arrayed in the first direction and in a second direction perpendicular to the first direction. That is, the semiconductor pillars 152 may be arrayed in a matrix form. Thus, the semiconductor pillars 152 may be arranged in rows and columns in a plan view. The rows may be parallel with the first direction, and the columns may be parallel with the second direction.

Each of the semiconductor pillars 152 may include a first doped portion 152a and a second doped portion 152b which are sequentially stacked. The first doped portion 152a may contact a top surface of any one of the conductive regions 112. The first doped portions 152a may be doped with dopants of a second conductivity type opposite to the first conductivity type. The second doped portions 152b may be doped with dopants of the first conductivity type. Thus, the first and second doped portions 152a and 152b in each semiconductor pillar 152 may contact each other to form a metallurgical junction constituting a PN diode. Some of the diodes may be connected to each of the conductive regions 112. The semiconductor pillar 152 including the first and second doped portions 152a and 152b may correspond to the selection element 12 (e.g., a switching device) illustrated in FIG. 1.

The semiconductor pillars 152 including the first and second doped portions 152a and 152b may include a single crystalline semiconductor material. For example, the semiconductor pillars 152 may include a single crystalline silicon material.

Lower electrodes 156 may be disposed in the openings on the semiconductor pillars 152. The lower electrodes 156 may be electrically connected to upper portions (e.g., the second doped portions 152b) of the semiconductor pillars 152, respectively.

Top surfaces of the lower electrodes 156 may be substantially coplanar with a top surface of the dielectric layer 120. That is, a vertical distance between the top surface of the substrate 100 and the top surfaces of the lower electrodes 156 may be substantially equal to a vertical distance between the top surface of the substrate 100 and the top surface of the dielectric layer 120. The lower electrodes 156 may include a conductive material having a low reactivity. For example, the lower electrodes 156 may include a conductive metal nitride material such as a titanium nitride (TiN) layer, a tantalum nitride (TaN) layer and/or a titanium-aluminum nitride (TiAlN) layer.

Ohmic patterns 154 may be disposed between the lower electrodes 156 and the semiconductor pillars 152. The ohmic patterns 154 may provide ohmic contacts between the lower electrodes 156 and the semiconductor pillars 152. That is, the ohmic patterns 154 may reduce the contact resistance between lower electrodes 156 and the semiconductor pillars 152. The ohmic patterns 154 may include a metal-semiconductor compound material layer. The semiconductor material contained in the ohmic patterns 154 may be the same material as contained in the second doped portions 152b of the semiconductor pillars 152. For example, the ohmic patterns 154 may include a cobalt-semiconductor compound material (e.g., a cobalt silicide layer), a nickel-semiconductor compound material (e.g., a nickel silicide layer) and/or a titanium-semiconductor compound material (e.g., a titanium silicide layer).

A first interlayer dielectric layer 160 may be disposed on the dielectric layer 120 and the lower electrodes 156. The first interlayer dielectric layer 160 may include an oxide material, a nitride material and/or an oxynitride material. The first interlayer dielectric layer 160 may be a single-layered material or a multi-layered material.

Variable resistive patterns 164 may be disposed in second openings 162 penetrating the first interlayer dielectric layer 160. The variable resistive patterns 164 may be in contact with top surfaces of the lower electrodes 156. The second openings 162 may have a groove shape extending in the second direction. Thus, the variable resistive patterns 164 in the second openings 162 may also extend in the second direction to have a line shape. Each of the variable resistive patterns 164 may contact the plurality of lower electrodes 156 that are arrayed in the second direction to constitute a single column. As described above, the lower electrodes 156 may be two dimensionally arrayed in matrix form. That is, the lower electrodes 156 may be disposed in a plurality of rows and in a plurality of columns. The number of the variable resistive patterns 164 may be two or more.

The variable resistive patterns 164 may include a phase changeable material. In this case, the variable resistive patterns 164 may be changed into any one of two or more different resistive states according to an electrical pulse signal applied to the variable resistive patterns 164. A width of top surfaces of the variable resistive patterns 164 may be greater than a width of bottom surfaces of the variable resistive patterns 164. That is, an area of the bottom surface of the respective variable resistive patterns 164 may be less than an area of the top surface of the respective variable resistive patterns 164. Each of the variable resistive patterns 164 may have a program region that directly contacts the lower electrode 156. The program regions of the variable resistive patterns 164 correspond to a region in which phase transformation actually occurs during operation of the semiconductor device.

The phase changeable material of the variable resistive patterns 164 may include at least one of tellurium (Te) and selenium (Se) corresponding to chalcogenide elements. The phase change material may further include at least one of germanium (Ge), stibium (Sb), bismuth (Bi), lead (Pb), tin (Sn), silver (Ag), arsenic (As), sulfur (S), silicon (Si), phosphorus (P), oxygen (O) and nitrogen (N). For example, each of the variable resistive patterns 164 may include at least one of a Ge—Sb—Te compound material, an As—Sb—Te compound material, an As—Ge—Sb—Te compound material, a Sn—Sb—Te compound material, a Ag—In—Sb—Te compound material, an In—Sb—Te compound material, a 5A group element —Sb—Te compound material, a 6A group element —Sb—Te compound material, a 5A group element —Sb—Se compound material and a 6A group element —Sb—Se compound material.

Upper electrodes 166 may be disposed on the first interlayer dielectric layer 160 and the variable resistive patterns 164. The upper electrodes 166 may be in contact with top surfaces of the variable resistive patterns 164, respectively. Thus, the upper electrodes 166 may extend in the second direction to have a line shape, like the variable resistive patterns 164. Each upper electrode 166 may be in contact with a whole area of the top surface of the variable resistive pattern 164 thereunder. The upper electrodes 166 may include a conductive metal nitride layer, for example, a titanium nitride layer, a tantalum nitride layer and/or a titanium-aluminum nitride layer.

A second interlayer dielectric layer 170 may be disposed on the first interlayer dielectric layer 160 and the upper electrodes 166. The second interlayer dielectric layer 170 may include an oxide material, a nitride material and/or an oxynitride material.

Plugs 174 may be disposed in third openings 172 penetrating the second interlayer dielectric layer 170, respectively. The plugs 174 may contact the upper electrodes 166, respectively. The third openings 172 may have a groove shape extending in the second direction. Thus, the plugs 174 may also have a groove shape extending in the second direction. The number of the plugs 174 may be two or more. That is, the plugs 174 may extend in parallel in the second direction. Further, the plugs 174 may contact top surfaces of the upper electrodes 166, respectively. The plugs 174 may include a tungsten layer, a copper layer or an aluminum layer.

Bit lines 180 may be disposed on the plugs 174. The bit lines 180 may be electrically connected to the plugs 174, respectively. For example, the bit lines 180 may be in contact with top surfaces of the plugs 174, respectively. The bit lines 180 may also extend in a second direction to be parallel with each other. As described above, according to an embodiment, the variable resistive patterns 164, the upper electrodes 166, the plugs 174 and the bit lines 180 may extend in the second direction to be parallel with each other. The bit lines 180 may include a metal material. For example, the bit lines 180 may include a tungsten layer, a copper layer or an aluminum layer.

According to the embodiment described above, the conductive regions 112 may include a metal-semiconductor compound material, and the semiconductor pillars 152 may include a single crystalline semiconductor material. Thus, the electrical resistance of the conductive regions 112 constituting the word lines and the electrical resistance of the semiconductor pillars 152 constituting the switching elements may be remarkably reduced to provide a high performance and highly integrated semiconductor device.

Further, if the conductive regions 112 are formed by injecting first or second type dopants into the semiconductor substrate 100, the dopants in the conductive regions 112 may be out-diffused into the semiconductor pillars 152 in a subsequent process such as a thermal treatment process. In this case, characteristics of the switching elements formed in the semiconductor pillars 152 may be degraded. However, according to the embodiment of the inventive concept, the conductive regions 112 may be formed to include a metal-semiconductor compound material. Thus, the characteristics of the switching elements formed in the semiconductor pillars 152 may be prevented from being degraded resulting in a highly reliable semiconductor device.

Now, methods of fabricating a semiconductor device according to a first embodiment of the inventive concept will be described below.

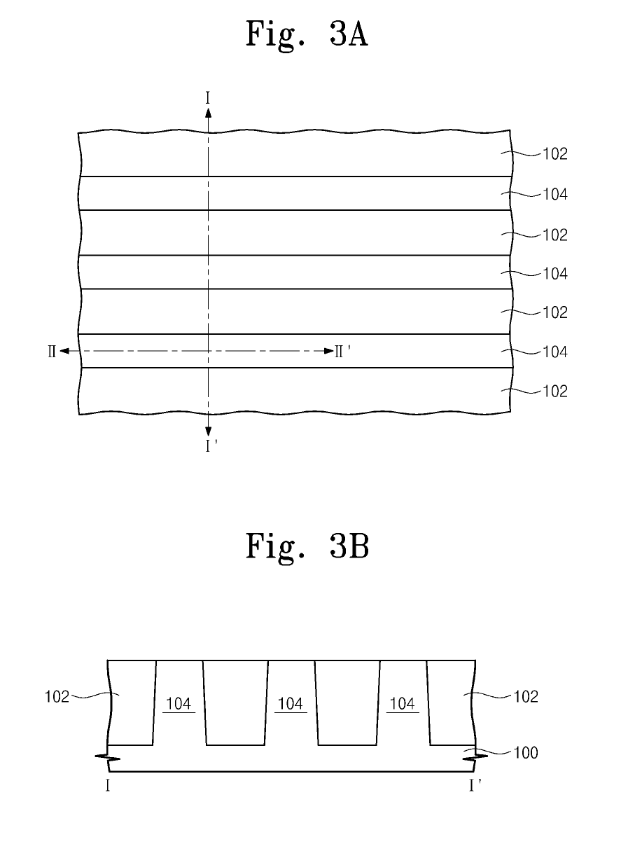

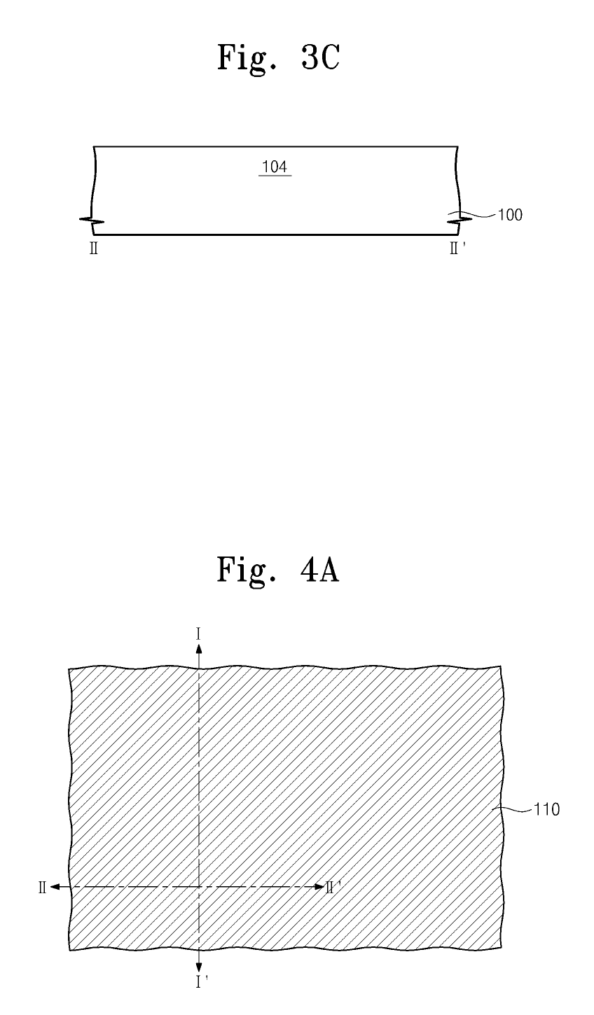

FIGS. 3A to 7A are plan views illustrating a method of fabricating a semiconductor device according to a first embodiment of the inventive concept. Further, FIGS. 3B to 7B are cross sectional views taken along a line I-I′ of FIGS. 3A to 7A, respectively, to illustrate a method of fabricating a semiconductor device according to a first embodiment of the inventive concept. Moreover, FIGS. 3C to 7C are cross-sectional views taken along a line II-II′ of FIGS. 3A to 7A, respectively, to illustrate a method of fabricating a semiconductor device according to a first embodiment of the inventive concept.

Referring to FIGS. 3A, 3B and 3C, a substrate 100 may be provided. The substrate 100 may include a semiconductor substrate. Isolation patterns 102 may be formed in the substrate 100. The isolation patterns 102 may be formed by forming trenches in the substrate 100. The isolation patterns 102 may be provided by forming trenches in the substrate 100 and filling the trenches with an insulating material. The isolation patterns 102 may extend in a first direction to be parallel with each other.

The isolation patterns 102 may define active portions 104 disposed therebetween. That is, the active portions 104 may be defined between the adjacent isolation patterns 102. The active portions 104 may be doped with dopants of a first conductivity type. For example, a well region doped with dopants of the first conductivity type may be formed in the substrate 100, and the isolation patterns 102 may be formed in the well region of the first conductivity type. Thus, the active portions 104 may have the first conductivity type. The well region may be formed before or after forming the isolation patterns 102.

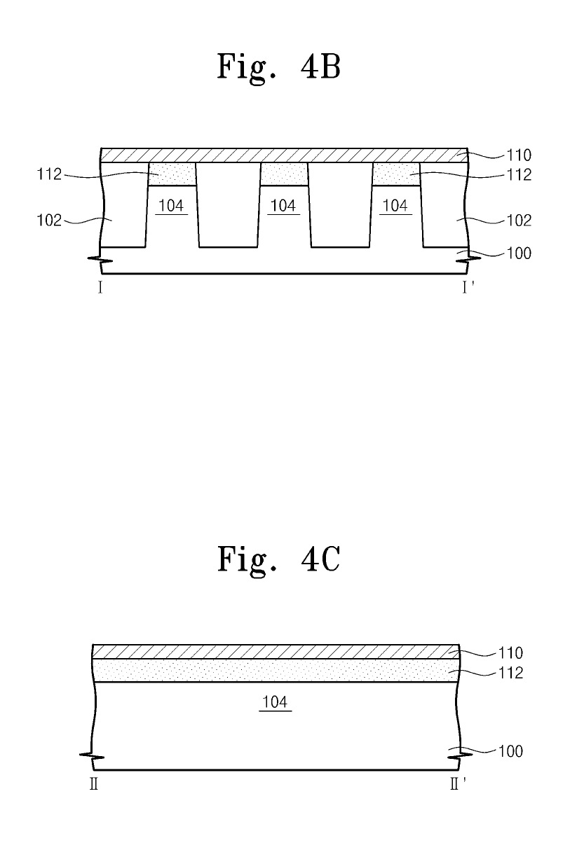

Referring to FIGS. 4A, 4B and 4C, a metal layer 110 may be formed on the substrate 100 after formation of the isolation patterns 102. That is, the metal layer 110 may be formed to cover the active portions 104 and the isolation patterns 102. The metal layer 110 may directly contact the active portions 104. The metal layer 110 may be formed to include at least one of a cobalt layer, a titanium layer, a tungsten layer and a nickel layer.

A first annealing process may be performed after formation of the metal layer 110. During the first annealing process, the metal layer 110 and the active portions 104 may react with each other to form conductive regions 112 at interfaces between the metal layer 110 and the active portions 104. The conductive regions 112 may include a metal-semiconductor compound material which is formed by reaction of metal atoms in the metal layer 110 and semiconductor atoms in the active portions 104. For example, when the semiconductor substrate 100 is a silicon substrate, the conductive regions 112 may include a metal silicide layer corresponding to a metal-silicon compound material.

Each of the active portions 104 may correspond to a part of the substrate 100 surrounded by the isolation patterns 102. In the event that the substrate 100 is a single crystalline silicon substrate, the active portions 104 may also correspond to a single crystalline silicon material. In this case, the metal silicide layer, which is formed by reaction of the metal atoms in the metal layer 110 and the semiconductor atoms in the active portions 104, may have a polycrystalline state. That is, the conductive regions 112 may have a polycrystalline state. Alternatively, the conductive regions 112 may have an amorphous state.

In another embodiment, the conductive regions 112 may be formed by injecting dopants of a second conductivity type opposite to the first conductivity type into the active portions 104. In this case, the conductive regions 112 may have a polycrystalline state or an amorphous state even though the active portions 104 have a single crystalline state. However, the conductive regions 112 may be transformed to have a single crystalline state in a subsequent thermal treatment process.

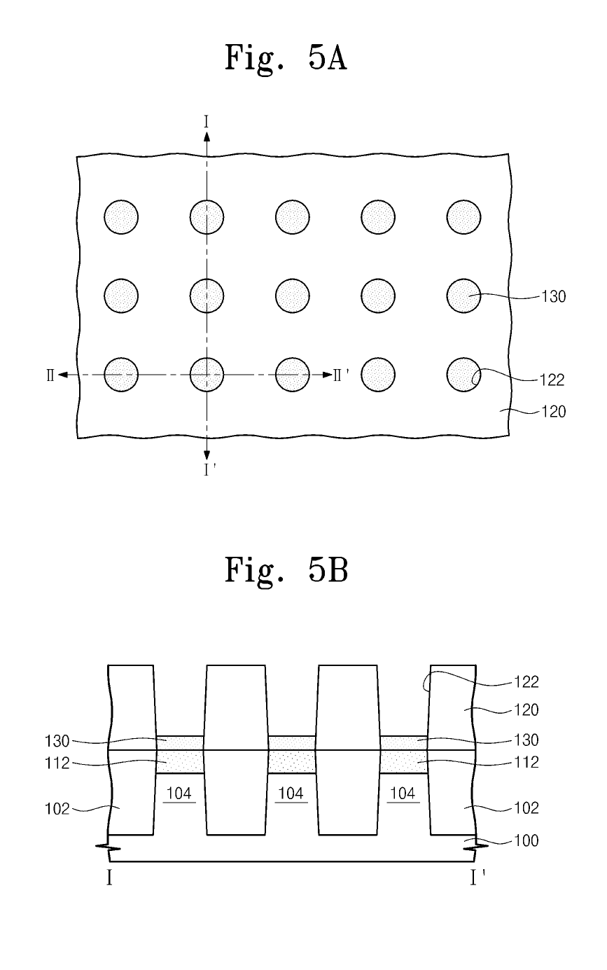

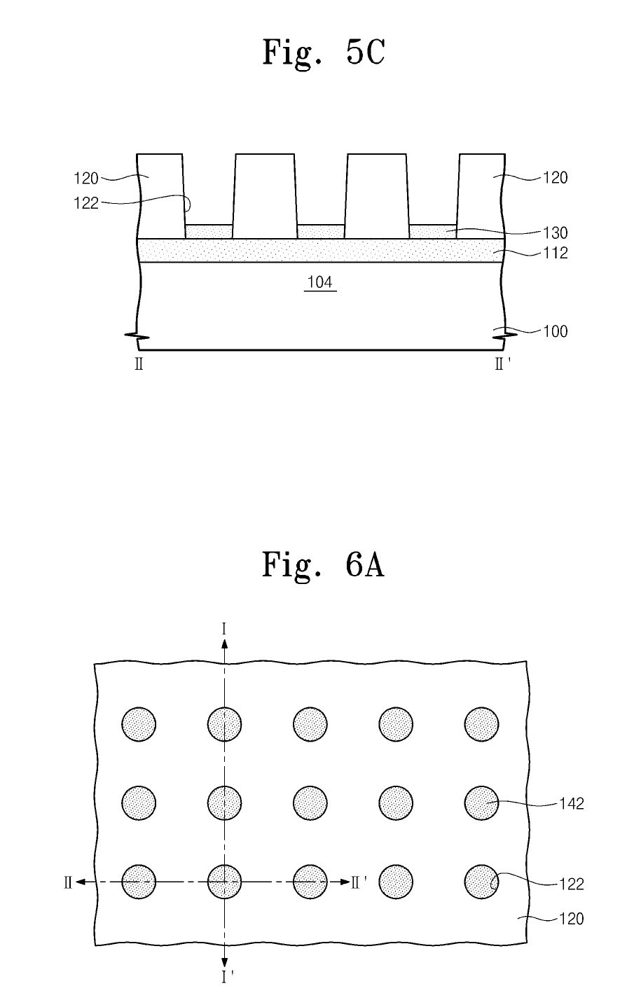

Referring to FIGS. 5A, 5B and 5C, the metal layer 110 existing on the isolation patterns 102, which is not reacted with the active portions 104 during the first annealing process, may be removed after the first annealing process. A second annealing process may be performed after removal of the unreacted metal layer 110. A process temperature of the second annealing process may be higher than that of the first annealing process. Due to the second annealing process, electrical resistance of the conductive regions 112 may be reduced.

A dielectric layer 120 may be formed on the substrate having the conductive regions 112. The dielectric layer 120 may be formed to have first openings 122 exposing portions of the respective conductive regions 112. The first openings 122 may be formed by forming the dielectric layer 120 on the substrate and patterning the dielectric layer 120. The dielectric layer 120 may include a multi-layered material. For example, the dielectric layer 120 may include an oxide layer, a nitride layer and an oxide layer which are sequentially stacked.

The number of the first openings 122 may be two or more. Similarly, the number of the conductive regions 112 may be two or more. The plurality of first openings 122 may be arrayed in the first direction and in a second direction crossing the first direction. The plurality of conductive region 112 may extend in the first direction to be parallel with each other. The plurality of conductive region 112 may be separated from each other in the second direction. Some of the first openings 122 may be arrayed in a single line parallel with the first direction, thereby constituting a single row. Further, some of the first openings 122 may be arrayed in a single line parallel with the second direction, thereby constituting a single column. The first openings 122 in the single row may expose some portions of one of the conductive regions 112, respectively. The first openings 122 in the single column may expose the conductive regions 112, respectively.

Preliminary semiconductor patterns 130 may be formed in the first openings 122, respectively. The preliminary semiconductor patterns 130 may be formed using an epitaxial process that employs the conductive regions 112 exposed by the first openings 122 as seed layers. The preliminary semiconductor patterns 130 formed using the epitaxial process may have the same lattice structure and plane orientation as the conductive regions 112 used as seed layers of the epitaxial process. Thus, if the conductive regions 112 have a polycrystalline state, the preliminary semiconductor patterns 130 may also have a polycrystalline state. Similarly, if the conductive regions 112 have an amorphous state, the preliminary semiconductor patterns 130 may also have an amorphous state.

The preliminary semiconductor patterns 130 may cover bottom surfaces of the first openings 122. A thickness of the preliminary semiconductor patterns 130 may be less than that of the dielectric layer 120. As such, the preliminary semiconductor patterns 130 may fill lower potions of the first openings 122, and upper portions of the first openings 122 may maintain an empty state.

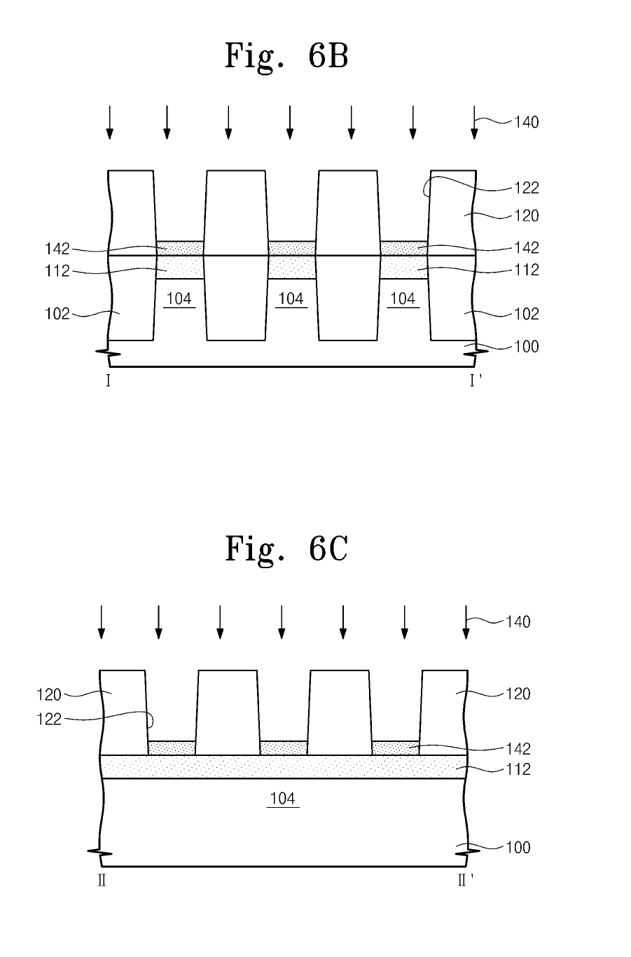

Referring to FIGS. 6A, 6b and 6C, a crystallization process 140 may be applied to the preliminary semiconductor patterns 130 having a polycrystalline state or an amorphous state, thereby forming buffer semiconductor patterns 142. The buffer semiconductor patterns 142 may have a single crystalline state. That is, the crystallization process 140 may change a phase of the preliminary semiconductor patterns 130 into a single crystalline state. For example, the buffer semiconductor patterns 142 may correspond to single crystalline silicon materials.

The crystallization process 140 may include irradiating a laser onto the preliminary semiconductor patterns 130. Alternatively, the crystallization process 140 may include heating the preliminary semiconductor patterns 130. In another embodiment, the crystallization process 140 may include irradiating a laser onto the preliminary semiconductor patterns 130 and/or heating the preliminary semiconductor patterns 130.

If a thickness of the preliminary semiconductor patterns 130 increases, an amount of the laser irradiated onto the preliminary semiconductor patterns 130 or an amount of the heat energy supplied to the preliminary semiconductor patterns 130 may also be increased in order to completely crystallize the preliminary semiconductor patterns 130. Further, the laser and/or the heat energy may also be supplied to a peripheral circuit region as well as to a cell array region of the semiconductor device during the crystallization process 140. Thus, if a thickness of the preliminary semiconductor patterns 130 increases, characteristics of peripheral circuits in the peripheral circuit region may be degraded due to the laser and/or the heat energy supplied to the peripheral circuit region. In an embodiment, the thickness of the preliminary semiconductor patterns 130 may be appropriately designed so that the preliminary semiconductor patterns 130 are easily crystallized without any degradation of the characteristics of the peripheral circuits during the crystallization process 140.

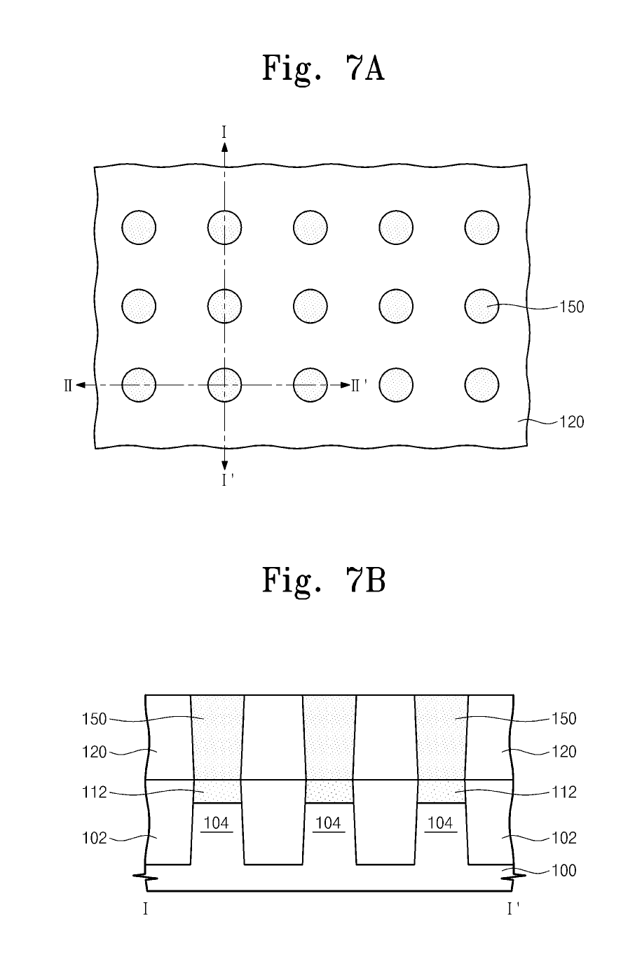

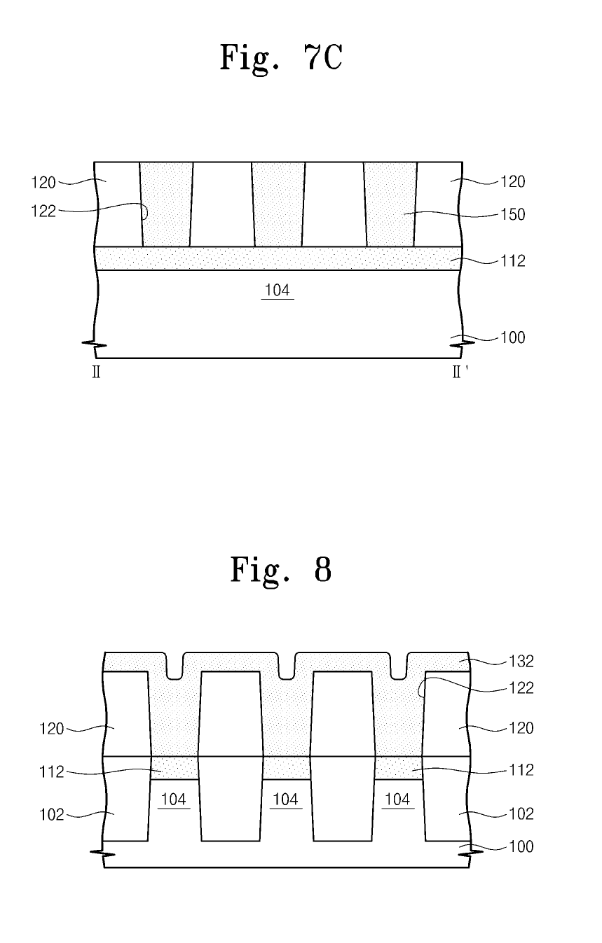

Referring to FIGS. 7A, 7B and 7C, after formation of the buffer semiconductor patterns 142, an epitaxial process may be performed using the buffer semiconductor patterns 142 having a single crystalline state as seed layers. The epitaxial process may be performed to form epitaxial layers filling the first openings 122 on the buffer semiconductor patterns 142. The epitaxial layers may also be formed on top surfaces of the dielectric layer 120 located outside the first openings 122. The epitaxial layers may have the same lattice structure and plane orientations as the buffer semiconductor patterns 142 used as seed layers during the epitaxial process. Thus, in the event that the buffer semiconductor patterns 142 have a single crystalline state, the epitaxial layers may also have a single crystalline state.

A planarization process may be applied to the substrate including the epitaxial layers. The planarization process may be performed using the dielectric layer 120 as a planarization stop layer. Thus, after the planarization process, the epitaxial layers outside the first openings 122 may be removed to form filling semiconductor patterns 150 existing in the first openings 122. Alternatively, the epitaxial layers may be formed only in the first openings 122 without any excessive epitaxial layers formed outside the first openings 122. In this case, the epitaxial layers may correspond to the filling semiconductor patterns 150 even without the planarization process.

The method of a semiconductor device according to the first embodiment will now be described with reference again to FIGS. 2A, 2B and 2C.

Referring to FIGS. 2A, 2B and 2C, an etch-back process may be applied to the filling semiconductor patterns 150. As a result of the etch-back process, the filling semiconductor patterns 150 may be recessed. Thus, top surfaces of the recessed filling semiconductor patterns 150 may be lower than the top surface of the dielectric layer 120.

Dopants of the second conductivity type may be injected into lower portions of the recessed filling semiconductor patterns 150, and dopants of the first conductivity type may be injected into upper portions of the recessed filling semiconductor patterns 150. Injections of the second conductivity type dopants and the first conductivity type dopants may lead to formation of semiconductor pillars 152.

Each of the semiconductor pillars 152 may include a first doped portion 152a contacting the conductive regions 112 and a second doped portion 152b on the first doped portions 152a. The first doped portions 152a may correspond to the lower portions of the recessed filling semiconductor patterns 150, which are doped with the first conductivity type dopants. The second doped portions 152b may correspond to the upper portions of the recessed filling semiconductor patterns 150, which are doped with the second conductivity type dopants.

Alternatively, the first doped portions 152a and the second doped portions 152b may be formed using an in-situ doping process. That is, the second conductivity type dopants and the first conductivity type dopants may be sequentially introduced into a process chamber during the epitaxial process.

As described above, the semiconductor pillars 152 may be formed using the epitaxial process that employs the single crystalline buffer semiconductor patterns 142 as seed layers. Thus, the semiconductor pillars 152 may also have a single crystalline state.

In the event that the epitaxial processes are performed using the conductive regions 112 with a polycrystalline state or an amorphous state as seed layers, the epitaxial layers and the semiconductor pillars 152 may also have a polycrystalline state or an amorphous state. In general, the polycrystalline layers and the amorphous layers may contain multiple crystalline defects (such as vacancies or dislocations) as compared to a single crystalline layer. Thus, if the epitaxial processes are performed using the conductive regions 112 of a polycrystalline state or an amorphous state as seed layers, the epitaxial layers and the semiconductor pillars 152 may also contain multiple crystalline defects. The cause of the crystalline defects in the conductive regions 112 having a polycrystalline state or an amorphous state is due to the transfer into the epitaxial layers and the semiconductor pillars 152 during the epitaxial processes. However, according to the embodiment described above, the epitaxial processes may be performed using the conductive regions 112 and/or the buffer semiconductor patterns 142 having a single crystalline state. That is, the semiconductor pillars 152 constituting the switching elements 12 illustrated in FIG. 1 may also be formed to have a single crystalline state. Thus, a highly reliable semiconductor device may be provided.

Referring again to FIGS. 2A, 2B and 2C, ohmic patterns 154 may be formed on the semiconductor pillars 152, respectively. The ohmic patterns 154 may be formed by forming a metal layer contacting top surfaces of the semiconductor pillars 152 and performing an annealing process to react the metal layer and the semiconductor pillars 152. After formation of the ohmic patterns 154, an unreacted metal layer may be removed. On the basis of a top surface of the substrate 100, top surfaces of the ohmic patterns 154 may be located at a lower level than a top surface of the dielectric layer 120. The metal layer may be formed of a cobalt layer, a nickel layer or a titanium layer. That is, the ohmic patterns 154 may be formed of a cobalt silicide layer, a nickel silicide layer or a titanium silicide layer.

A lower electrode layer filling the first openings 122 on the ohmic patterns 154 may be formed on an entire top surface of the substrate including the ohmic patterns 154. The lower electrode layer may be planarized until the dielectric layer 120 is exposed, thereby forming lower electrodes 156. That is, the lower electrodes 156 may be formed to fill the first openings 122 on the ohmic patterns 154. After the planarization process, top surfaces of the lower electrodes 156 may be substantially coplanar with the top surface of the dielectric layer 120. The lower electrode layer may be formed of a conductive metal nitride layer, for example, a titanium nitride layer, a tantalum nitride layer and/or a titanium-aluminum nitride layer.

A first interlayer dielectric layer 160 may be formed on the substrate including the lower electrodes 156. The first interlayer dielectric layer 160 may be patterned to form second openings 162 penetrating the first interlayer dielectric layer 160. Each of the second openings 162 may be formed to have a groove shape extending in the second direction. Each of the second openings 162 may expose the lower electrodes 156 constituting a single column.

A variable resistive layer may be formed on an entire top surface of the substrate including the second openings 162. The variable resistive layer may be formed to fill the second openings 162. In an embodiment, the variable resistive layer may be formed of a phase changeable material. The phase changeable material may include at least one of tellurium (Te) and selenium (Se) corresponding to chalcogenide elements. The phase changeable material may further include at least one of germanium (Ge), stibium (Sb), bismuth (Bi), lead (Pb), tin (Sn), silver (Ag), arsenic (As), sulfur (S), silicon (Si), phosphorus (P), oxygen (O) and nitrogen (N). For example, the variable resistive layer may include at least one of a Ge—Sb—Te compound material, an As—Sb—Te compound material, an As—Ge—Sb—Te compound material, a Sn—Sb—Te compound material, a Ag—In—Sb—Te compound material, an In—Sb—Te compound material, a 5A group element —Sb—Te compound material, a 6A group element —Sb—Te compound material, a 5A group element —Sb—Se compound material and a 6A group element —Sb—Se compound material.

The variable resistive layer may be planarized until the first interlayer dielectric layer 160 is exposed, thereby forming variable resistive patterns 164 in the second openings 162. The planarization process may split the variable resistive layer into the variable resistive patterns 164 which are separated from each other. The variable resistive patterns 164 may be formed to have a line shape extending in the second direction.

An upper electrode layer may be formed on the substrate including the variable resistive patterns 164, and the upper electrode layer may be patterned to form upper electrodes 166 on the variable resistive patterns 164. The upper electrodes 166 may be formed to be parallel with the variable resistive patterns 164. That is, the upper electrodes 166 may be formed to contact top surfaces of the variable resistive patterns 164. The upper electrode layer may be formed of the same material as the lower electrode layer.

A second interlayer dielectric layer 170 may be formed on the substrate including the upper electrodes 166. The second interlayer dielectric layer 170 may be patterned to form third openings 172 that expose the upper electrodes 164. The third openings 172 may be formed to have a groove shape extending in the second direction.

A conductive layer filling the third openings 172 may be formed on the substrate including the third openings 172. The conductive layer may be planarized until the second interlayer dielectric layer 170 is exposed, thereby forming plugs 174. That is, the plugs 174 may be formed to remain in the third openings 172. The conductive layer may be formed of a metal layer such as a tungsten layer, a copper layer or an aluminum layer.

A bit line conductive layer may be formed on the second interlayer dielectric layer 170 and the plugs 174. The bit line conductive layer may be patterned to form bit lines 180 which are respectively connected to the plugs 174.

A first modified embodiment of the method of fabricating the semiconductor device according to the first embodiment will be described below.

FIGS. 8 to 10 are cross-sectional views taken along a line I-I ′ of FIG. 2A to illustrate the first modified embodiment of the method of fabricating the semiconductor device according to the first embodiment of the inventive concept.

Referring to FIG. 8, isolation patterns 102 defining active portions 104, conductive regions 112, a dielectric layer 120 and first openings 122 may be formed in and on a substrate 100 using the same manner as described with reference to FIGS. 3A to 5A, 3B to 5B, and 3C to 5C.

A preliminary semiconductor layer 132 may be formed in the first openings 122 and on the dielectric layer 120. The preliminary semiconductor layer 132 may be formed using a deposition process, for example, a chemical vapor deposition (CVD) process. The preliminary semiconductor layer 132 may be formed of a polycrystalline semiconductor material or an amorphous semiconductor material.

The preliminary semiconductor layer 132 may be formed to cover the inner walls and the bottom surface of the first openings 122. In an embodiment, the preliminary semiconductor layer 132 may be formed to completely fill the first openings 122. In another embodiment, the preliminary semiconductor layer 132 may be formed to partially fill the first openings 122.

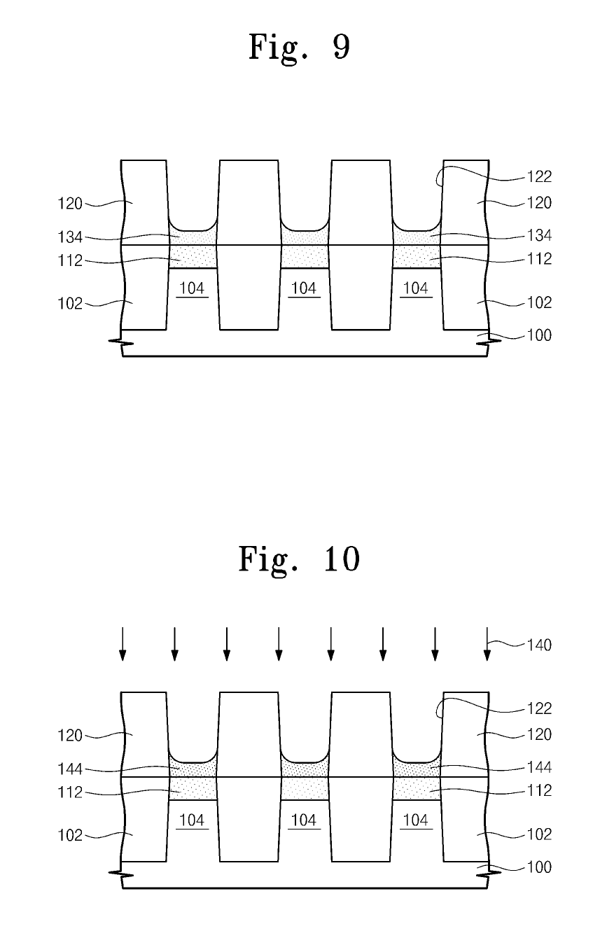

Referring to FIG. 9, the preliminary semiconductor layer 132 may be partially etched to remove the preliminary semiconductor layer 132 located at outside region of the first openings 122 and to retain the preliminary semiconductor layer 132 located in the first openings 122. Due to a partial etching of the preliminary semiconductor layer 132, preliminary semiconductor patterns 134 may be formed in the first openings 122. The partial etching of the preliminary semiconductor layer 132 may be performed using a wet etching process. The preliminary semiconductor patterns 134 may correspond to portions of the preliminary semiconductor layer 132, which are left in the first openings 122 after partially etching the preliminary semiconductor layer 132. Thus, the preliminary semiconductor patterns 134 may still have a polycrystalline state or an amorphous state.

A vertical thickness of the preliminary semiconductor patterns 134 may increase as the patterns 134 become closer to the sidewalls of the first openings 122. That is, the vertical thickness of central portions of the preliminary semiconductor patterns 134 may be less than that of edges of the preliminary semiconductor patterns 134.

Referring to FIG. 10, a crystallization process 140 may be applied to the preliminary semiconductor patterns 134 having a polycrystalline state or an amorphous state, thereby forming buffer semiconductor patterns 144. The buffer semiconductor patterns 144 may have a single crystalline state. That is, the crystallization process 140 may change a phase of the preliminary semiconductor patterns 134 into a single crystalline state. For example, the buffer semiconductor patterns 144 may correspond to single crystalline silicon materials. The crystallization process 140 may be performed using the same manner as described with reference to FIGS. 6A, 6B and 6C.

If a thickness of the preliminary semiconductor patterns 132 increases, an amount of the laser irradiated onto the preliminary semiconductor patterns 132 or an amount of the heat energy supplied to the preliminary semiconductor patterns 132 may also be increased in order to completely crystallize the preliminary semiconductor patterns 132. Further, the laser and/or the heat energy may also be supplied to a peripheral circuit region as well as to a cell array region of the semiconductor device during the crystallization process 140. Thus, if a thickness of the preliminary semiconductor patterns 132 increases, characteristics of peripheral circuits in the peripheral circuit region may be degraded due to the laser and/or the heat energy supplied to the peripheral circuit region. In the present embodiment, the thickness of the preliminary semiconductor patterns 132 may be appropriately designed so that the preliminary semiconductor patterns 132 are easily crystallized without any degradation of the characteristics of the peripheral circuits during the crystallization process 140.

Subsequently, as described with reference to FIGS. 7A, 7B and 7C, an epitaxial process may be performed using the buffer semiconductor patterns 144 as seed layers to form filling semiconductor patterns 150 in the first openings 122. Semiconductor pillars 152, ohmic patterns 154, lower electrodes 156, variable resistive patterns 164, upper electrodes 166, plugs 174 and bit lines 180 may then be formed using the same manner as described with reference to FIGS. 2A, 2B and 2C.

Hereinafter, a second modified embodiment of the method of fabricating the semiconductor device according to the first embodiment will be described.

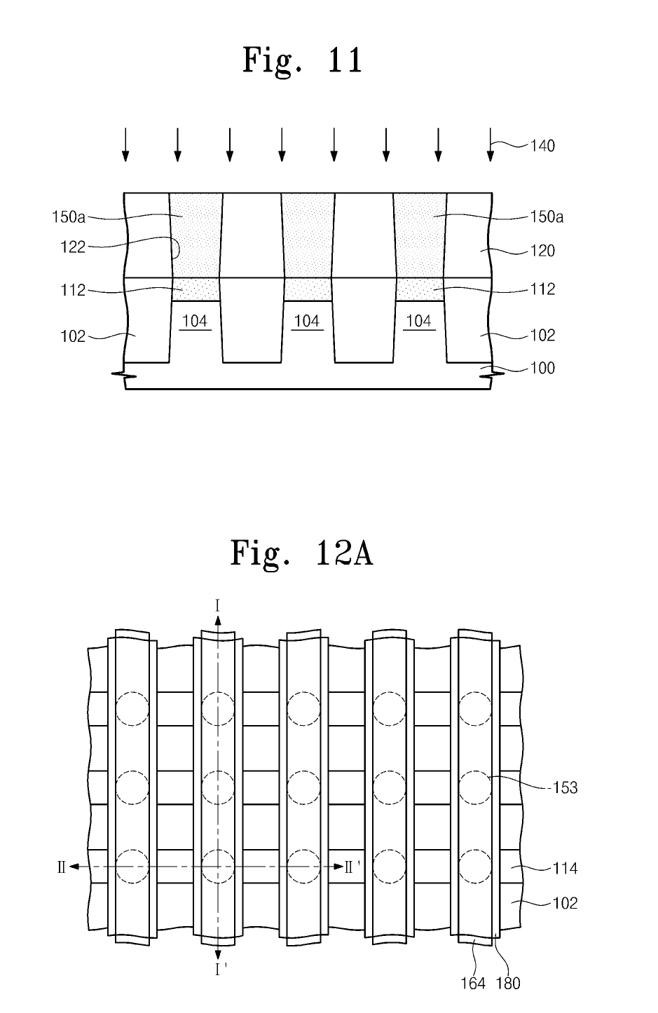

FIG. 11 is a cross sectional view taken along a line I-I′ of FIG. 2A to illustrate a second modified embodiment of the method of fabricating the semiconductor device according to the first embodiment of the inventive concept.

Referring to FIG. 11, isolation patterns 102 defining active portions 104, conductive regions 112, a dielectric layer 120 and first openings 122 may be formed in and on a substrate 100 using the same manner as described with reference to FIGS. 3A to 5A, 3B to 5B, and 3C to 5C.

A preliminary semiconductor layer filling the first openings 122 may be formed on the dielectric layer 120. The preliminary semiconductor layer may be formed to have a polycrystalline state or an amorphous state. The preliminary semiconductor layer may be planarized using the dielectric layer 120 as a planarization stop layer, thereby forming preliminary semiconductor patterns in the first openings 122.

A crystallization process 140 may be applied to the preliminary semiconductor patterns having a polycrystalline state or an amorphous state, thereby forming filling semiconductor patterns 150a having a single crystalline state. That is, the crystallization process 140 may change a phase of the preliminary semiconductor patterns into a single crystalline state. The crystallization process 140 may be performed using the same manner as described with reference to FIGS. 6A, 6B and 6C.

Subsequently, semiconductor pillars 152, ohmic patterns 154, lower electrodes 156, variable resistive patterns 164, upper electrodes 166, plugs 174 and bit lines 180 may be formed using the same manner as described with reference to FIGS. 2A, 2B and 2C.

Now, a semiconductor device according to a second embodiment of the inventive concept will be described. The semiconductor device according to the second embodiment may be similar to the semiconductor device according to the first embodiment. In the second embodiment, the same elements as illustrated in the first embodiment are denoted using the same reference numerals or the same reference designators. To avoid duplicate explanations, descriptions to the same elements as set forth in the previous embodiment may be omitted or briefly mentioned in the present embodiment. That is, differences between the present embodiment and the previous embodiment will be mainly described in detail hereinafter.

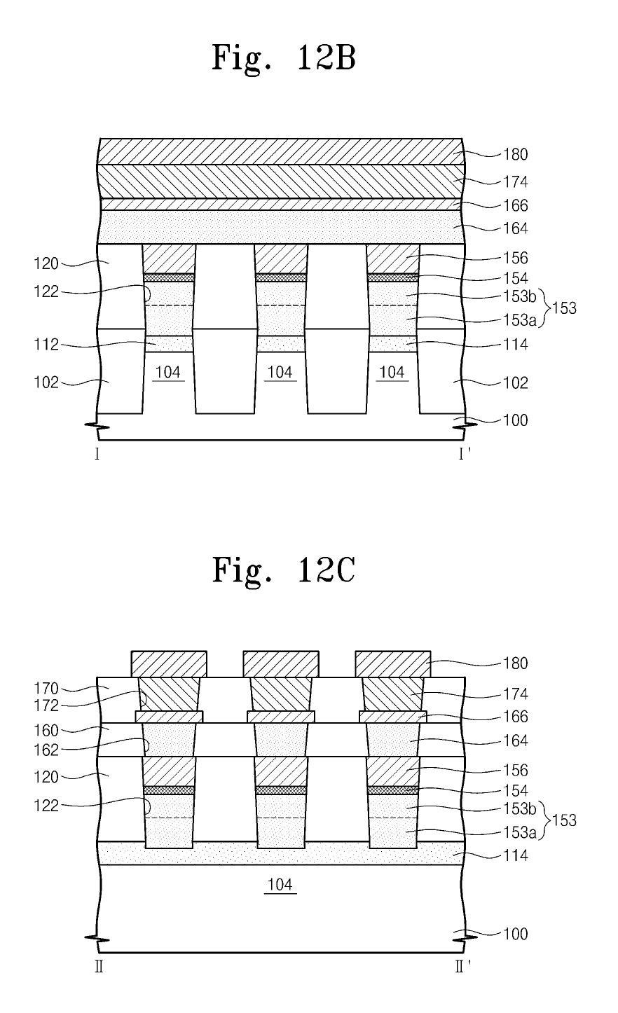

FIG. 12A is a plan view illustrating a semiconductor device according to a second embodiment of the present general inventive concept. FIG. 12B is a cross-sectional view taken along a line I-I′ of FIG. 12A to illustrate a semiconductor device according to a second embodiment of the inventive concept, and FIG. 12C is a cross-sectional view taken along a line II-II′ of FIG. 12A to illustrate a semiconductor device according to a second embodiment of the inventive concept.

Referring to FIGS. 12A, 12B and 12C, isolation patterns 102 in a substrate 100 may define active portions 104 doped with dopants of a first conductivity type. Conductive regions 114 may be disposed in the active portions 104, respectively. The conductive regions 114 may have a line shape extending in a first direction. Top surfaces of the conductive regions 114 may be lower than top surfaces of the isolation patterns 102.

The conductive regions 114 may be doped with dopants of a second conductivity type. The second conductivity type may be different from the first conductivity type. For example, the active portions 104 may be doped with P-type dopants, and the conductive regions 114 may be doped with N-type dopants. The conductive regions 114 may correspond to the word lines WL illustrated in FIG. 1.

A dielectric layer 120 may be disposed on the conductive regions 114 and the isolation patterns 102. First openings 122 may penetrate the dielectric layer 120 to expose the conductive regions 114. Semiconductor pillars 153 may be disposed in the first openings 122, respectively. The semiconductor pillars 153 may be two-dimensionally arrayed along a first direction and along a second direction crossing the first direction. That is, the semiconductor pillars 153 may be arrayed in a matrix form. As such, the semiconductor pillars 153 may be arrayed in a plurality of rows and in a plurality of columns when viewed from a plan view. The rows may be parallel with the first direction, and the columns may be parallel with the second direction.

Each of the semiconductor pillars 153 may include a first doped portion 153a and a second doped portion 153b which are sequentially stacked. The first doped portion 153a may contact a top surface of any one of the conductive regions 114. The first doped portions 153a may be doped with dopants of the same conductivity type (e.g., the second conductivity type) as the conductive regions 114. The second doped portions 153b may be doped with dopants of a different conductivity type (e.g., the first conductivity type) from the first doped portions 153a. Thus, the first and second doped portions 153a and 153b in each semiconductor pillar 153 may contact to form a metallurgical junction constituting a PN diode. The semiconductor pillar 153 including the first and second doped portions 153a and 153b may correspond to the selection element 12 (e.g., a switching device) illustrated in FIG. 1.

The semiconductor pillars 153 including the first and second doped portions 153a and 153b may include a single crystalline semiconductor material. For example, the semiconductor pillars 153 may include a single crystalline silicon material.

Bottom surfaces of the semiconductor pillars 153 may be lower than top surfaces of the conductive regions 114, as illustrated in FIG. 12C. Thus, a first group of lower sidewalls of the semiconductor pillars 153 may be covered with the conductive regions 114. Moreover, the bottom surfaces of the semiconductor pillars 153 may be lower than top surfaces of the isolation patterns 102, as illustrated in FIG. 12B. Thus, a second group of lower sidewalls of the semiconductor pillars 153 may be covered with the isolation patterns 102.

An ohmic pattern 154 and a lower electrode 156 may be sequentially stacked on the semiconductor pillar 153 in each of the first openings 122. A first interlayer dielectric layer 160 may be disposed on the dielectric layer 120 and the lower electrodes 156, and variable resistive patterns 164 may be disposed in second openings 162 penetrating the first interlayer dielectric layer 160. Upper electrodes 166 may be disposed on the variable resistive patterns 164. A second interlayer dielectric layer 170 may be disposed on the first interlayer dielectric layer 160 and the upper electrodes 166. Plugs 174 may be disposed in third openings 172 penetrating the second interlayer dielectric layer 170, respectively. Bit lines 180 may be disposed on the plugs 174.

Methods of fabricating a semiconductor device according to a second embodiment of the present general inventive concept will be described below.

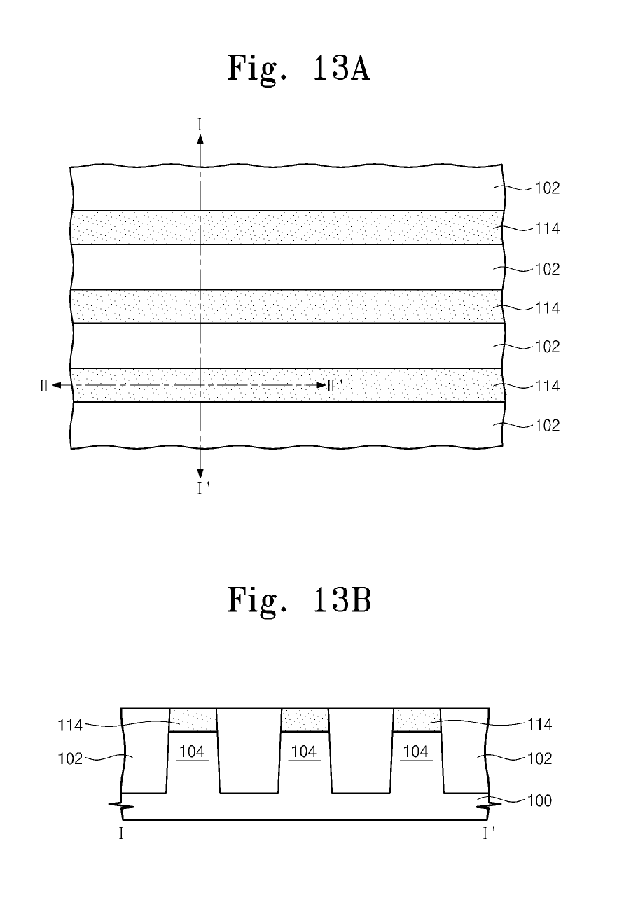

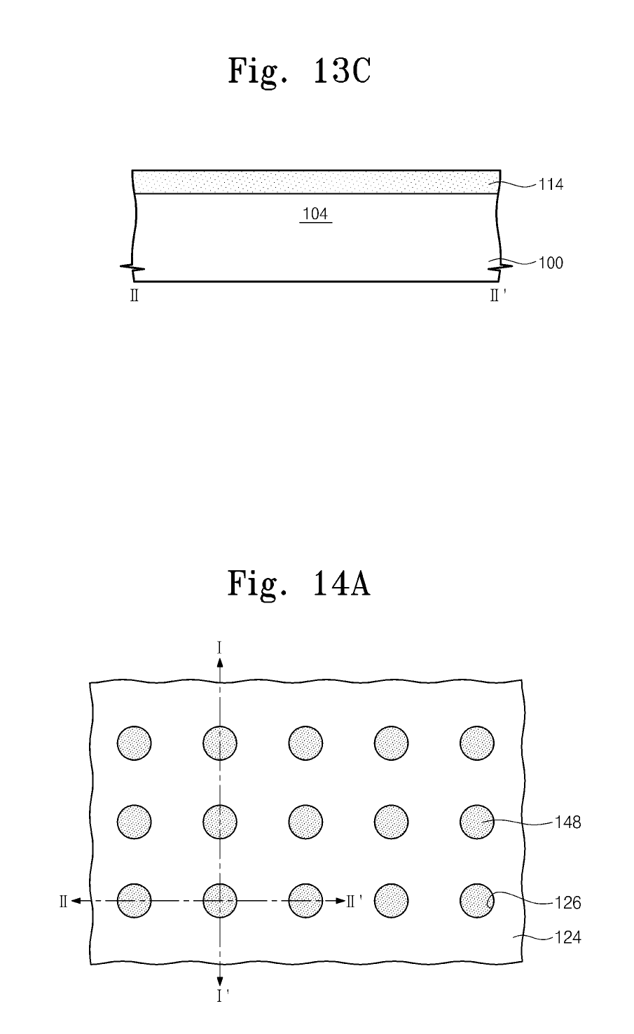

FIGS. 13A to 15A are plan views illustrating methods of fabricating a semiconductor device according to a second embodiment of the present general inventive concept. FIGS. 13B to 15B are cross-sectional views taken along a line I-I′ of FIGS. 13A to 15A, respectively. FIGS. 13C to 15C are cross-sectional views taken along a line II-II′ of FIGS. 13A to 15A, respectively.

Referring to FIGS. 13A, 13B and 13C, isolation patterns 102 may be formed in a substrate 100 of a first conductivity type using the same manner as described with reference to FIGS. 3A, 3B and 3C. The isolation patterns 102 may define active portions 104.

After formation of the isolation patterns 102, dopants of a second conductivity type may be injected into the active portions 104 to form conductive regions 114. The dopants of a second conductivity type may be injected into the active portions 104 using an ion implantation process. The conductive regions 114 may be formed to extend in a first direction.

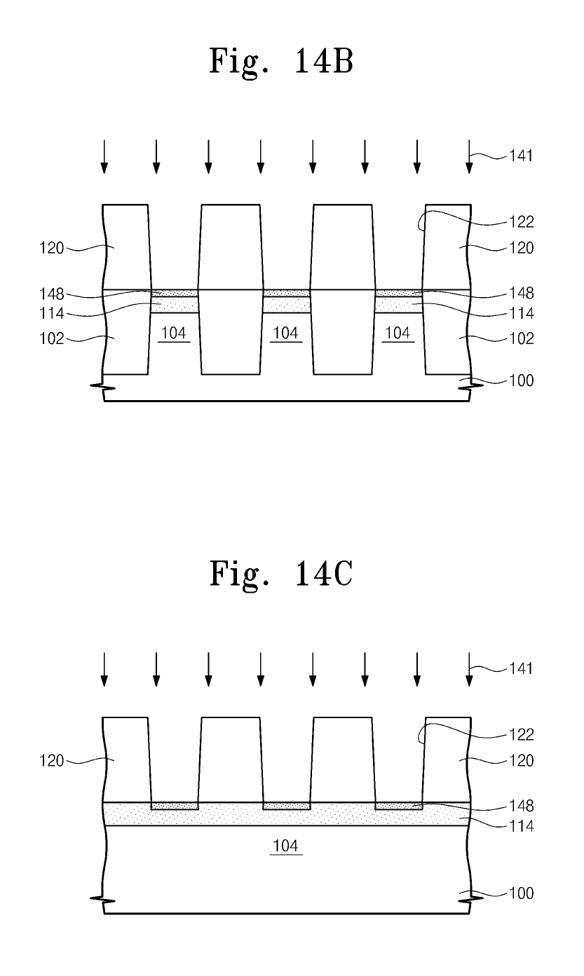

Referring to FIGS. 14A, 14B and 14C, a dielectric layer 120 may be formed on the substrate including the conductive regions 114. Portions of each of the conductive regions 114 may be exposed by first openings 122 penetrating the dielectric layer 120.

After formation of the dielectric layer 120 and the first openings 122, a crystallization process 141 may be applied to the conductive regions 114 to form single crystalline buffer semiconductor patterns 148 in the first openings 122. The crystallization process 141 may include irradiating a laser onto the conductive regions 114 exposed by the first openings 122. The crystallization process 141 may change a phase of the upper portions of the conductive regions 114 exposed by the first openings 122 into a single crystalline state. That is, the upper portions of the conductive regions 114 changed into a single crystalline state may correspond to the buffer semiconductor patterns 148.

Top surfaces of the buffer semiconductor patterns 148 may be substantially coplanar with top surfaces of the conductive regions 114. The top surfaces of the buffer semiconductor patterns 148 may be substantially coplanar with a bottom surface of the dielectric layer 120. Bottom surfaces of the buffer semiconductor patterns 148 may be located at a lower level than the top surfaces of the conductive regions 114. The bottom surfaces of the buffer semiconductor patterns 148 may be located at a lower level than top surfaces of the isolation patterns 102.

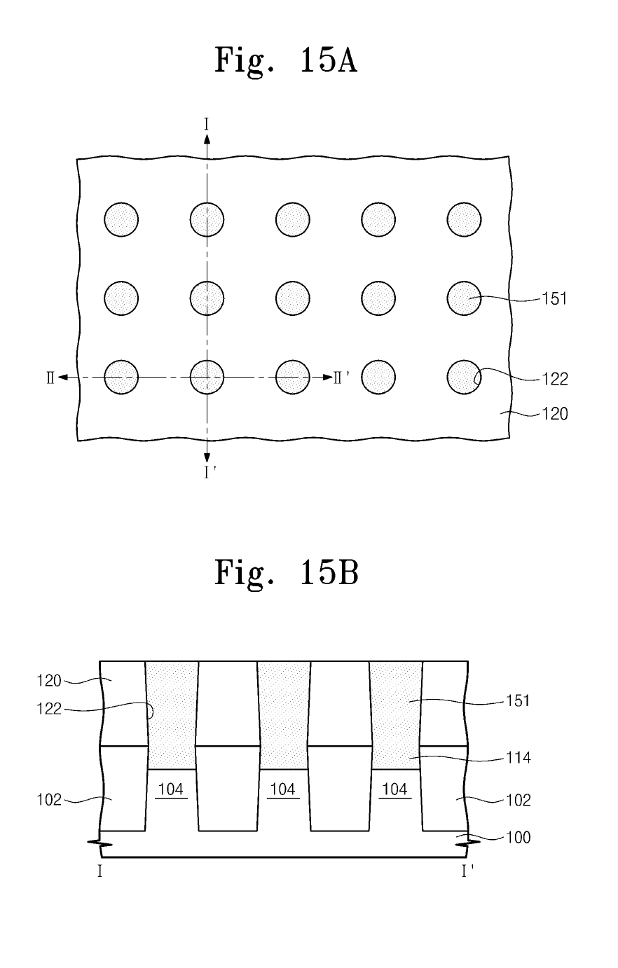

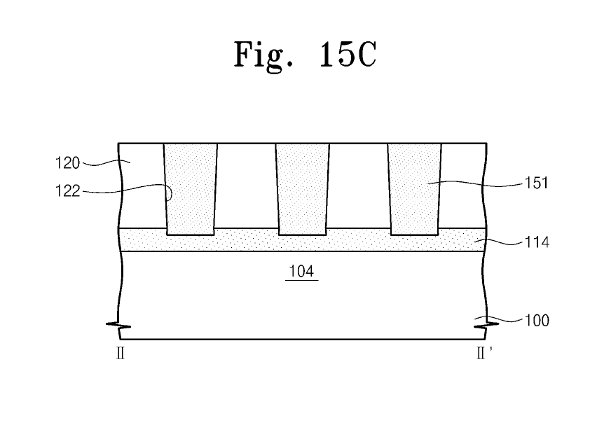

Referring to FIGS. 15A, 15B and 15C, an epitaxial process may be applied to the substrate including the buffer semiconductor patterns 148, thereby forming epitaxial layers filling the first openings 122. The epitaxial process may be performed using the buffer semiconductor patterns 148 as seed layers. In addition, the epitaxial layers may be excessively formed outside the first openings 122. The epitaxial layers may have the same lattice structure and plane orientation as the buffer semiconductor patterns 148 used as the seed layers of the epitaxial process. Thus, if the buffer semiconductor patterns 148 have a single crystalline state, the epitaxial layers may also have a single crystalline state.

A planarization process may be applied to the substrate including the epitaxial layers. The planarization process may be performed using the dielectric layer 120 as a planarization stop layer. Thus, after the planarization process, the epitaxial layers outside the first openings 122 may be removed to form filling semiconductor patterns 151 existing in the first openings 122.

The methods of fabricating the semiconductor device according to the second embodiment will be described below with reference again to FIGS. 12A, 12B and 12C.

Referring to FIGS. 12A, 12B and 12C, an etch-back process may be applied to the filling semiconductor patterns 151. As a result of the etch-back process, the filling semiconductor patterns 151 may be recessed to form recessed filling semiconductor patterns 153. Thus, top surfaces of the recessed filling semiconductor patterns 153 may be lower than the top surface of the dielectric layer 120. Dopants of the second conductivity type may be injected into lower portions of the recessed filling semiconductor patterns 153, and dopants of the second conductivity type may be injected into upper portions of the recessed filling semiconductor patterns 153. Injections of the first conductivity type dopants and the second conductivity type dopants may lead to formation of semiconductor pillars 153.

Each of the recessed semiconductor pillars 153 may include a first doped portion 153a contacting the conductive regions 114 and a second doped portion 153b on the first doped portions 153a.

Alternatively, the first doped portions 153a and the second doped portions 153b may be formed using an in-situ doping process. That is, the second conductivity type dopants and the first conductivity type dopants may be sequentially introduced into a process chamber during the epitaxial process.

Subsequently, ohmic patterns 154, lower electrodes 156, a first interlayer dielectric layer 160, variable resistive patterns 164, upper electrodes 166, a second interlayer dielectric layer 170, plugs 174 and bit lines 180 may be formed using the same manner as described with reference to FIGS. 2A, 2B and 2C.

The semiconductor devices according to the embodiments of the present general inventive concept described above may be encapsulated using various packaging techniques. For example, the semiconductor devices according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a system in package (SIP) technique, a multi-chip package (MCP) technique, a wafer-level fabricated package (WFP) technique and a wafer-level processed stack package (WSP) technique. The package in which the semiconductor device according to one of the above embodiments is mounted may further include at least one additional semiconductor device (e.g., a controller and/or a logic device) that controls the semiconductor device.

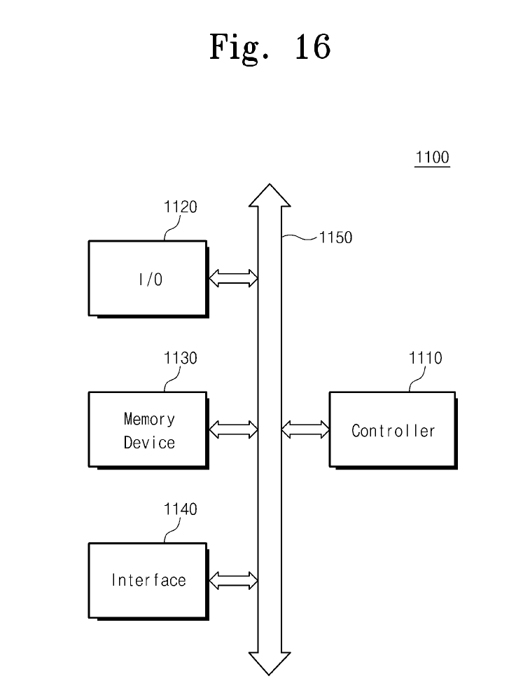

FIG. 16 is a schematic block diagram illustrating an example of electronic systems including the semiconductor devices according to embodiments of the inventive concept.

Referring to FIG. 16, an electronic system 1100 according to an embodiment of the present general inventive concept may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard or a display unit. The memory device 1130 may store data and/or commands. The memory device 1130 may include at least one of the three dimensional semiconductor memory devices according to the embodiments described above. The memory device 1130 may further include other types of semiconductor memory devices which are different from the three dimensional semiconductor memory devices described above. For example, the memory device 1130 may further include a magnetic memory device, a phase change memory device, a dynamic random access memory (DRAM) device and/or a static random access memory (SRAM) device. The interface unit 1140 may transmit electrical data to a communication network or may receive electrical data from a communication network. The interface unit 1140 may operate by wireless communication or by cable. For example, the interface unit 1140 may include an antenna for wireless communication or a transceiver for cable communication. Although not shown in the drawings, the electronic system 1100 may further include a fast DRAM device and/or a fast SRAM device which acts as a cache memory for improving an operation of the controller 1110.

The electronic system 1100 may be applied to a personal digital assistant (PDA), a portable computer, a web tablet, a wireless phone, a mobile phone, a digital music player or a memory card. The electronic system 1100 may also be applied to another electronic product that receives or transmits information data by wireless communication.

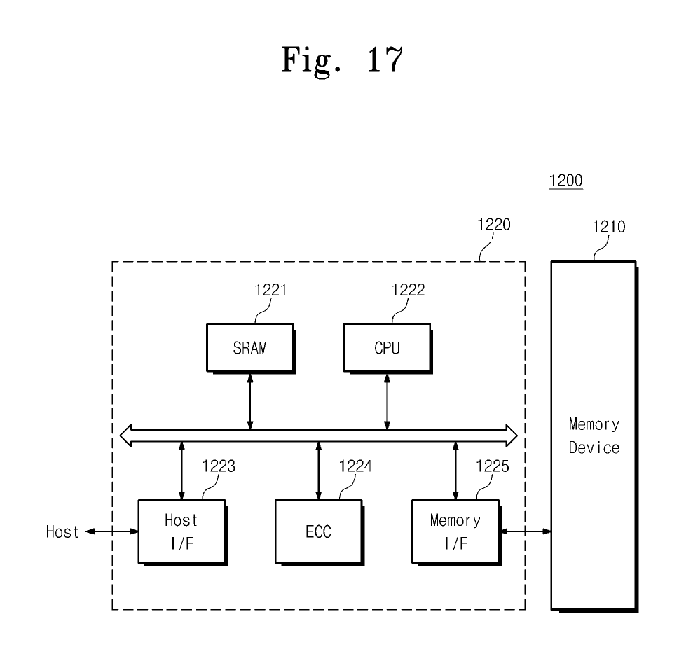

FIG. 17 is a schematic block diagram illustrating an example of memory cards including the semiconductor devices according to the embodiments of the inventive concept.

Referring to FIG. 17, a memory card 1200 according to an embodiment of the present general inventive concept may include a memory device 1210. The memory device 1210 may include at least one of the three dimensional semiconductor memory devices according to the various embodiments described above. In other embodiments, the memory device 1210 may further include other types of semiconductor memory devices which are different from the three dimensional semiconductor memory devices according to the embodiments described above. For example, the memory device 1210 may further include a magnetic memory device, a phase change memory device, a dynamic random access memory (DRAM) device and/or a static random access memory (SRAM) device. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) unit 1224. The ECC unit 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may replace hard disks of computer systems as solid state disks as solid state disks of the computer systems.

According to the embodiments of the present general inventive concept set forth above, a dielectric layer is formed on a substrate having conductive regions. The conductive regions are exposed by openings that penetrate the dielectric layer. Buffer semiconductor patterns are formed on the exposed conductive regions. An epitaxial process is performed using the buffer semiconductor patterns as seed layers, thereby forming filling semiconductor patterns in the openings. As such, a highly reliable and highly integrated semiconductor device may be realized.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A method of fabricating a semiconductor device, the method comprising:
forming a conductive region in a substrate;
forming a dielectric layer on the substrate including the conductive region, the dielectric layer having an opening that exposes the conductive region;
forming a single crystalline buffer semiconductor pattern on the exposed conductive region; and
forming a filling semiconductor pattern in the opening using an epitaxial process employing the single crystalline buffer semiconductor pattern as a seed layer.

2. The method of claim 1, wherein forming the single crystalline buffer semiconductor pattern comprises:
forming a preliminary semiconductor pattern having an amorphous state or a polycrystalline state in the opening; and
crystallizing the preliminary semiconductor pattern.

3. The method of claim 2, wherein forming the preliminary semiconductor pattern includes performing an epitaxial process using the conductive region exposed by the opening as a seed layer.

4. The method of claim 2, wherein forming the preliminary semiconductor pattern comprises:
depositing a preliminary semiconductor layer to fill the opening; and
etching a portion of the preliminary semiconductor layer.

5. The method of claim 2, wherein a magnitude of a vertical thickness of the preliminary semiconductor pattern increases in accordance with a proximity to a sidewall of the opening.

6. The method of claim 2, wherein crystallizing the preliminary semiconductor pattern includes irradiating a laser onto the preliminary semiconductor pattern or heating the preliminary semiconductor pattern.

7. The method of claim 1, wherein the conductive region includes a metal-semiconductor compound material.

8. The method of claim 7, wherein forming the conductive region comprises:
forming a metal layer on the substrate;
applying a first annealing process to the substrate;
removing the metal layer; and
applying a second annealing process to the substrate,
wherein the second annealing process is performed at a higher temperature than a temperature of the first annealing process.

9. The method of claim 1, wherein the substrate has a first conductivity type,
wherein forming the conductive region includes injecting dopants of a second conductivity type into the substrate, and
wherein forming the single crystalline buffer semiconductor pattern includes crystallizing an upper portion of the conductive region exposed by the opening.

10. The method of claim 1, wherein the conductive region extends in a first direction, and the conductive region has a polycrystalline state or an amorphous state.

11. The method of claim 1, wherein forming the filling semiconductor pattern includes performing a planarization process using the dielectric layer as a planarization stop layer, after the epitaxial process.

12. The method of claim 1, further comprising:
forming a semiconductor pillar by respectively injecting first dopants and second dopants into a lower portion and an upper portion of the filling semiconductor pattern; and
forming a variable resistive pattern on the semiconductor pillar.

13. (canceled)

14. (canceled)

15. (canceled)

16. A method of fabricating a highly integrated semiconductor device, the method comprising:
forming a conductive region in a substrate;
providing a dielectric layer on the substrate, the dielectric layer having at least one perforation, wherein the at least one perforation uncovers at least a portion of the conductive region;
forming a single crystalline buffer semiconductor pattern on the uncovered conductive region; and
using an epitaxial process to form a filling semiconductor pattern in the at least one perforation wherein the single crystalline buffer semiconductor pattern is a seed layer.

17. The method of claim 16, wherein forming the single crystalline buffer semiconductor pattern comprises:
forming a preliminary semiconductor pattern having an amorphous state or a polycrystalline state in the perforation; and
crystallizing the preliminary semiconductor pattern.

18. A method of fabricating a highly integrated semiconductor device in a fabricated semiconductor device formed of a substrate having a conductive region thereon, the method comprising:
forming a perforated dielectric layer on the conductive region to provide at least one opening having an uncovered conductive region;
forming a single crystalline buffer semiconductor pattern on the at least one uncovered conductive region; and
using an epitaxial process to form a filling semiconductor pattern in the at least one opening wherein the single crystalline buffer semiconductor pattern is a seed layer.

19. The method of 18, wherein forming the single crystalline buffer semiconductor pattern comprises:
forming a preliminary semiconductor pattern having an amorphous state or a polycrystalline state in the at least one opening; and
crystallizing the preliminary semiconductor pattern.

20. The method of claim 18, wherein fabricating the fabricated semiconductor with a substrate having a conductive region thereon comprises:
forming a metal layer on the substrate;
applying a first annealing process to the substrate;
removing the metal layer; and
applying a second annealing process to the substrate,
wherein the second annealing process is performed at a higher temperature than a temperature of the first annealing process.

21. The method of claim 18, wherein the conductive region extends in a first direction, and the conductive region has a polycrystalline state or an amorphous state, the conductive regions are word lines.

22. The method of claim 18, further comprising:
sequentially stacking a first dopant portion and a second dopant portion to form a semiconductor pillar by respectively injecting first dopants and second dopants into a lower portion and an upper portion of the filling semiconductor pattern; and
forming a variable resistive pattern on the semiconductor pillar.

23. The method of claim 22, further comprising:
electrically connecting a plurality of semiconductor pillars to one of the conductive regions, wherein the semiconductor pillars are switching elements,
wherein the plurality of semiconductor pillars are arrayed in matrix form.
